(19) United States
(12) Patent Application Publication
(10) Pub. No.: US 2023/0250282 A1
(43) Pub. Date: Aug. 10, 2023

(54) RESIN COMPOSITION, PREPREG, FILM WITH RESIN, METAL FOIL WITH RESIN, METAL-CLAD LAMINATE, AND PRINTED WIRING BOARD

(71) Applicant: PANASONIC INTELLECTUAL PROPERTY MANAGEMENT CO., LTD., Osaka (JP)

(72) Inventors: Rihoko WATANABE, Osaka (JP); Jun YASUMOTO, Fukushima (JP); Hiroharu INOUE, Osaka (JP)

(73) Assignee: PANASONIC INTELLECTUAL PROPERTY MANAGEMENT CO., LTD., Osaka (JP)

(21) Appl. No.: 18/012,184

(22) PCT Filed: Jun. 14, 2021
(86) PCT No.: PCT/JP2021/022468

§ 371 Date: Dec. 21, 2022

(30) Foreign Application Priority Data
Jun. 24, 2020 (JP) 2020-109131

(51) Int. Cl. C08L 79/08; C08K 5/5313; C08K 5/5399; C08J 5/24; C08J 7/04; H05K 1/03

(52) U.S. Cl. CPC C08L 79/08; C08K 5/5313; C08K 5/5399; C08J 5/246; C08J 7/0427; H05K 1/0353; C08L 2205/03; C08L 2203/16; C08J 2309/06; C08J 2363/00; C08J 2379/08

(57) ABSTRACT

A resin composition contains a maleimide compound (A), a phosphine oxide compound (B), and an epoxy compound (C). The maleimide compound (A) includes a maleimide compound (A1) having an alkyl group, of which a carbon number is equal to or greater than six, and/or an alkylene group, of which a carbon number is equal to or greater than six. The phosphine oxide compound (B) has a structure expressed by the following formula (b0), where X is a monovalent or divalent hydrocarbon group having at least one aromatic ring or an alkylene group and n is either 1 or 2.

### TECHNICAL FIELD

The present disclosure generally relates to a resin composition, a prepreg, a film with resin, a sheet of metal foil with resin, a metal-clad laminate, and a printed wiring board. More particularly, the present disclosure relates to a resin composition containing a maleimide compound, and a prepreg, a film with resin, a sheet of metal foil with resin, a metal-clad laminate, and a printed wiring board, all of which use such a resin composition.

### BACKGROUND ART

Patent Literature 1 discloses a flame-retardant resin composition used for manufacturing a printed wiring board, for example. This flame-retardant resin composition contains: a resin component containing a bismaleimide compound; a curing agent; a phosphorus-based flame retardant; and a fluororesin filler. The phosphorus-based flame retardant is at least one selected from the group consisting of cyclophosphazene-based flame retardants and phosphate-based flame retardants.

However, the phosphorus-based flame retardant of Patent Literature 1 is easily thermally decomposed or hydrolyzed at a temperature lower than the temperature at the time of combustion. Adding such a phosphorus-based flame retardant to the flame-retardant resin composition may cause a decline in flame resistance, chemical resistance, and electrical characteristics.

### CITATION LIST

### Patent Literature

Patent Literature 1: JP 2018-044065 A

### SUMMARY OF INVENTION

An object of the present disclosure is to provide a resin composition, a prepreg, a film with resin, a sheet of metal foil with resin, a metal-clad laminate, and a printed wiring board, all of which contribute to improving flame resistance, chemical resistance, and electrical characteristics.

A resin composition according to an aspect of the present disclosure contains a maleimide compound (A), a phosphine oxide compound (B), and an epoxy compound (C). The maleimide compound (A) includes a maleimide compound (A1) having an alkyl group, of which a carbon number is equal to or greater than six, and/or an alkylene group, of which a carbon number is equal to or greater than six. The phosphine oxide compound (B) has a structure expressed by the following formula (b0):

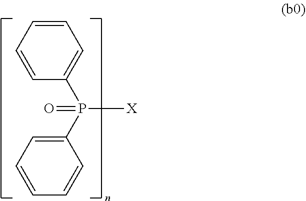

where X is a monovalent or divalent hydrocarbon group having at least one aromatic ring or an alkylene group and n is either 1 or 2.

A prepreg according to another aspect of the present disclosure includes: a base member; and a resin layer containing either the resin composition described above or a semi-cured product of the resin composition, each of which is impregnated into the base member.

A film with resin according to still another aspect of the present disclosure includes: a resin layer containing either the resin composition described above or a semi-cured product of the resin composition; and a supporting film supporting the resin layer.

A sheet of metal foil with resin according to yet another aspect of the present disclosure includes: a resin layer containing either the resin composition described above or a semi-cured product of the resin composition; and a sheet of metal foil bonded to the resin layer.

A metal-clad laminate according to yet another aspect of the present disclosure includes: an insulating layer containing either a cured product of the resin composition described above or a cured product of the prepreg described above; and a metal layer bonded to the insulating layer.

A printed wiring board according to yet another aspect of the present disclosure includes: an insulating layer containing either a cured product of the resin composition described above or a cured product of the prepreg described above; and conductor wiring formed on the insulating layer.

### BRIEF DESCRIPTION OF DRAWINGS

FIG. 1 is a schematic cross-sectional view illustrating a prepreg according to an exemplary embodiment of the present disclosure;

FIG. 2 is a schematic plan view illustrating a base member for use in the prepreg;

FIG. 3A is a schematic cross-sectional view illustrating a film with resin (and without a protective film) according to the exemplary embodiment of the present disclosure;

FIG. 3B is a schematic cross-sectional view illustrating a film with resin (and with a protective film) according to the exemplary embodiment of the present disclosure;

FIG. 4 is a schematic cross-sectional view illustrating a sheet of metal foil with resin according to the exemplary embodiment of the present disclosure;

FIG. 5 is a schematic cross-sectional view illustrating a metal-clad laminate according to the exemplary embodiment of the present disclosure;

FIG. 6A is a schematic cross-sectional view illustrating a printed wiring board (without interlevel connection) according to the exemplary embodiment of the present disclosure;

FIG. 6B is a schematic cross-sectional view illustrating a printed wiring board (with interlevel connection) according to the exemplary embodiment of the present disclosure; and

FIG. 7 is a schematic cross-sectional view illustrating a semiconductor package according to the exemplary embodiment of the present disclosure.

### DESCRIPTION OF EMBODIMENTS

1. Overview

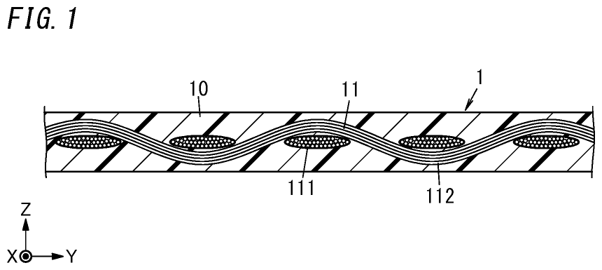

A resin composition according to an exemplary embodiment may be used as a board material. Examples of applications of the board material may include, without limitation, a prepreg 1, a film 2 with resin, a sheet of metal foil 3 with resin, a metal-clad laminate 4, and a printed wiring board 5 (see FIGS. 1-6B).

A resin composition according to this embodiment contains a maleimide compound (A), a phosphine oxide compound (B), and an epoxy compound (C). The present inventors discovered that a particular phosphine oxide compound (B) is unlikely to be thermally decomposed or hydrolyzed at a temperature lower than the temperature at the time of combustion. The present inventors also discovered that this particular phosphine oxide compound (B) reduces the chances of causing a decline in the properties of the maleimide compound (A) and the epoxy compound (C). The present inventors further discovered that a combination of a particular maleimide compound (A) and the epoxy compound (C) would contribute to improving the flame resistance, the chemical resistance, and the electrical characteristics.

Thus, the resin composition according to this embodiment may improve the flame resistance, the chemical resistance, and the electrical characteristics.

2. Details

Next, a resin composition according to this embodiment will be described in detail. After that, a prepreg 1, a film 2 with resin, a sheet of metal foil 3 with resin, a metal-clad laminate 4, a printed wiring board 5, and a semiconductor package 100 according to this embodiment will be described in detail with reference to the accompanying drawings. In some of the drawings, arrows indicating X, Y, and Z directions, which intersect at right angles with each other, are shown for the sake of convenience of description. Note that those arrows are insubstantial ones.

(1) Resin Composition

A resin composition according to this embodiment contains a maleimide compound (A), a phosphine oxide compound (B), and an epoxy compound (C). The resin composition preferably further contains a styrene copolymer (D). The resin composition preferably further contains an inorganic filler (E). Optionally, the resin composition may further contain other components (F). These constituent components of the resin composition will be described one by one.

<Maleimide Compound (A)>

The maleimide compound (A) includes a maleimide compound (A1) having an alkyl group, of which the carbon number is equal to or greater than six, and/or an alkylene group, of which the carbon number is equal to or greater than six. In other words, the maleimide compound (A1) includes at least one of the alkyl group, of which the carbon number is equal to or greater than six, or the alkylene group, of which the carbon number is equal to or greater than six. The upper limit value of the carbon number of the alkyl group is not limited to any particular value but may be 100, for example. The upper limit value of the carbon number of the alkylene group is not limited to any particular value but may be 100, for example. As can be seen, the maleimide compound (A1) has as long a chain as C6 or more, and therefore, is likely to improve the electrical characteristics of the board.

As used herein, the “electrical characteristics” mainly refer to dielectric characteristics. In this embodiment, the dielectric loss tangent may be reduced among other things. This may check a decline in transmission characteristics at radio frequencies.

The maleimide compound (A) preferably includes at least one selected from the group consisting of a maleimide compound (A3) expressed by the following formula (a3), a maleimide compound (A4) expressed by the following formula (a4), and a maleimide compound (A5) expressed by the following formula (a5). Adding such a maleimide compound (A) to the resin composition enables further improving the electrical characteristics of the board:

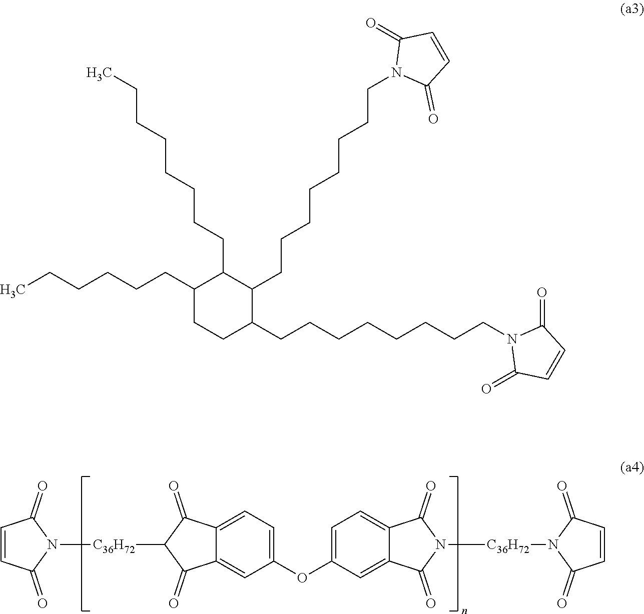

where n is an integer falling within the range from 1 to 10.

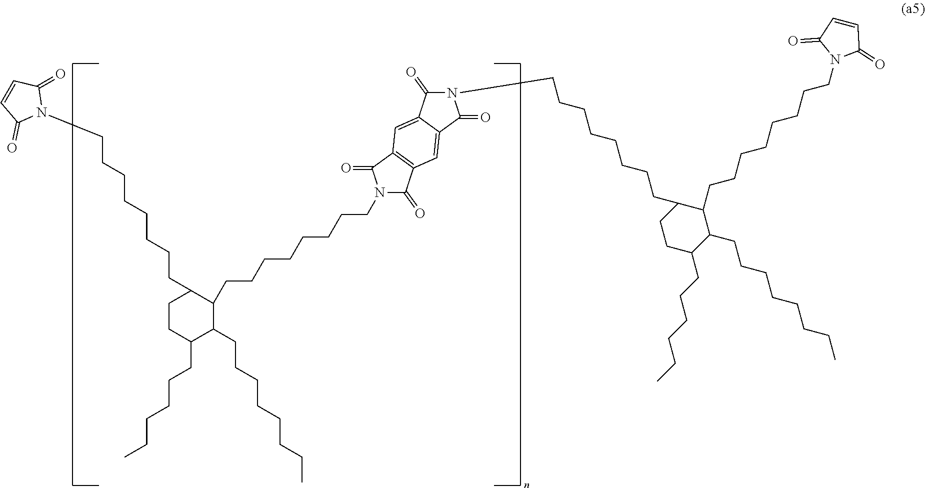

where n is an integer falling within the range from 1 to 10.

The maleimide compound (A1) preferably has a maleimide group equivalent equal to or greater than 400 g/eq. This enables further improving the electrical characteristics of the board. The upper limit value of the maleimide group equivalent is preferably equal to or less than 3000 g/eq and more preferably equal to or less than 2000 g/eq. Note that the maleimide group equivalent is a numerical value calculated by dividing the molecular weight of the maleimide compound (A) by the number of maleimide groups that the maleimide compound (A) has. That is to say, the maleimide group equivalent is a molecular weight per maleimide group.

The maleimide compound (A) preferably further includes a maleimide compound (A2) having a maleimide group equivalent less than 400 g/eq. This enables increasing the glass transition temperature (Tg) of the board. Increasing Tg of the board may reduce the chances of causing cracks in the board and may increase the reliability of interlevel connection. That is to say, this may reduce the chances of causing cracks in a board such as a multilayer printed wiring board even if stress is applied to the board in a thermal shock test, for example, thus reducing an increase in the resistance value of via holes and through holes. This may increase the reliability of interlevel connection. In recent years, in particular, as the wiring has been laid out increasingly densely with its feature size further reduced, the diameters of the via holes and through holes have been further decreased. Therefore, it is effective to increase Tg of the board to deal with circumstances such as these. The lower limit value of the maleimide group equivalent of the maleimide compound (A2) is preferably equal to or greater than 150 g/eq and more preferably equal to or greater than 200 g/eq.

The maleimide compound (A2) having a maleimide group equivalent less than 400 g/eq may, but does not have to, include a maleimide compound (A6) expressed by the following formula (a6), for example. The maleimide compound (A6) is 3,3′-dimethyl-5,5′-di ethyl-4,4′-diphenylmethane bismaleimide.

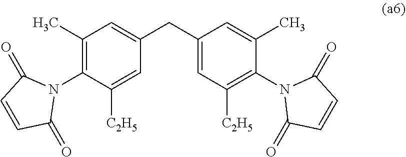 [SMILES: CCc1cc(Cc2cc(C)c(N3C(=O)C=CC3=O)c(CC)c2)cc(C)c1N1C(=O)C=CC1=O]

If the maleimide compound (A) further includes the maleimide compound (A2), the content of the maleimide compound (A2) with respect to the entire mass of the maleimide compound (A) is preferably equal to or greater than 20% by mass and equal to or less than 65% by mass and more preferably equal to or greater than 25% by mass and equal to or less than 60% by mass.

<Phosphine Oxide Compound (B)>

The phosphine oxide compound (B) mainly contributes to improving the flame resistance (in particular, the self-extinguishing property). That is to say, the phosphine oxide compound (B) may impart flame resistance to the board by making a coating of a phosphoric acid layer produced by thermal decomposition during the combustion form not only an oxygen cutoff layer but also a carbon coating on the resin surface due to dehydration action and thereby cutting off oxygen and heat.

The phosphine oxide compound (B) contains phosphorus, and therefore, may be used as a material for a flame retardant. The phosphine oxide compound (B) is preferably an additive flame retardant. In this case, flame retardants are classifiable into reactive flame retardants and additive flame retardants. A reactive flame retardant herein refers to a flame retardant which chemically bonds to another component through chemical reaction. On the other hand, the additive flame retardant herein refers to a flame retardant other than the reactive flame retardants. In other words, the additive flame retardant is just added without forming any chemical bond to any other component. The phosphine oxide compound (B) is not a salt, and therefore, may check a decline in chemical resistance due to alkali, for example. Thus, a cured product of the resin composition according to this embodiment is stable, even when coming into contact with various chemicals during the manufacturing process of a printed wiring board, with respect to those chemicals.

In addition, the phosphine oxide compound (B) is not easily compatible with the maleimide compound (A) and the epoxy compound (C), and therefore, is unlikely to inhibit the curing reaction of the maleimide compound (A) and the epoxy compound (C). Thus, it is presumed that the properties of the maleimide compound (A) and the epoxy compound (C) should be less likely to decline.

The phosphine oxide compound (B) is an organic phosphorus compound expressed by POR₃ (where R is an organic group such as an alkyl group or an aryl group). The molecular weight of the phosphine oxide compound (B) may be, but does not have to be, for example, equal to or greater than 400 and equal to or less than 700.

The phosphine oxide compound (B) has a structure expressed by the following formula (b0):

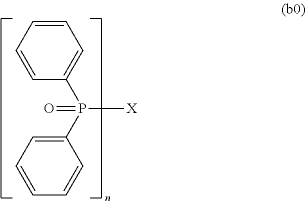

where X is a monovalent or divalent hydrocarbon group having at least one aromatic ring or an alkylene group and n is either 1 or 2.

In this case, the upper limit value of the number of aromatic rings (benzene rings) included in the hydrocarbon group in formula (b0) may be, but does not have to be, for example, equal to or less than five. The carbon number of the hydrocarbon group may be, but does not have to be, for example, equal to or greater than 6 and equal to or less than 14 (C6-C14).

The carbon number of the alkylene group in the formula (b0) may be, but does not have to be, equal to or greater than 1 and equal to or less than 10 (C1-C10).

The phosphine oxide compound (B), having the structure expressed by the formula (b0), is less likely to be thermally decomposed or hydrolyzed. In addition, the phosphine oxide compound (B) is less likely to inhibit the curing reaction of the maleimide compound (A) and the epoxy compound (C) than a general phosphoric acid ester does. Thus, it is presumed that the phosphine oxide compound (B) should be less likely to cause a decline in the properties of the maleimide compound (A) and the epoxy compound (C).

The phosphine oxide compound (B) preferably includes at least one selected from the group consisting of: a phosphine oxide compound (B1) expressed by the following formula (b1); a phosphine oxide compound (B2) expressed by the following formula (b2); a phosphine oxide compound (B3) expressed by the following formula (b3); a phosphine oxide compound (B4) expressed by the following formula (b4); a phosphine oxide compound (B5) expressed by the following formula (b5); a phosphine oxide compound (B6) expressed by the following formula (b6); a phosphine oxide compound (B7) expressed by the following formula (b7); and a phosphine oxide compound (B8) expressed by the following formula (b8):

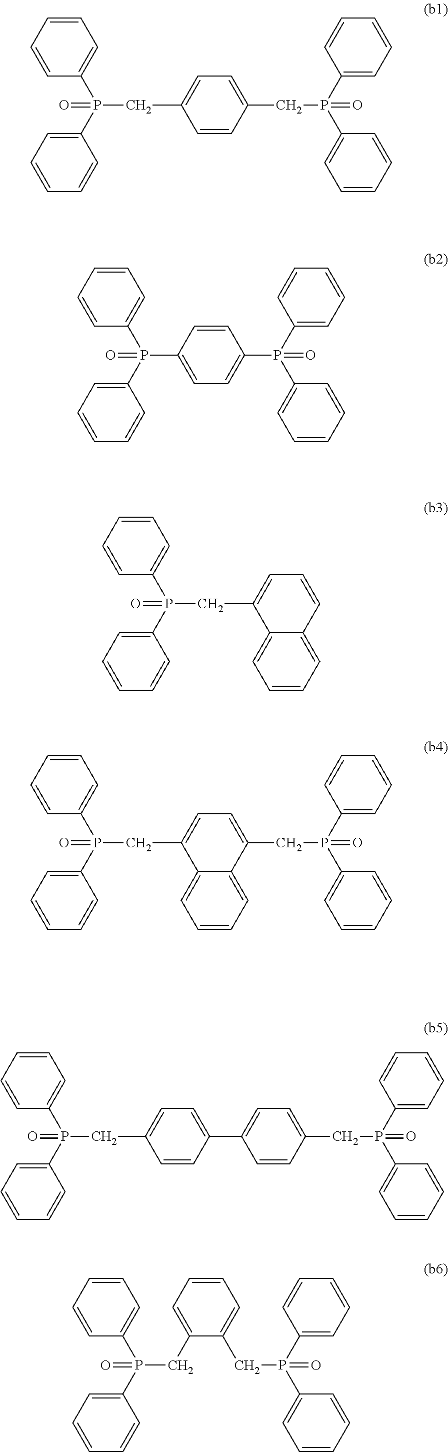

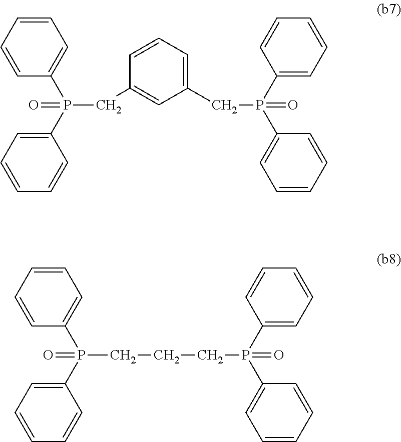 [SMILES: O=P(Cc1cccc(CP(=O)(c2ccccc2)c2ccccc2)c1)(c1ccccc1)c1ccccc1 ; O=P(CCCP(=O)(c1ccccc1)c1ccccc1)(c1ccccc1)c1ccccc1]

These phosphine oxide compounds (B1)-(B8) are exemplary additive flame retardants. The phosphine oxide compound (B1), among other things, is particularly effective in improving the chemical resistance.

In this case, the chemical resistance mainly refers to alkali resistance. Improving the chemical resistance reduces, even if the board is subjected to alkali treatment under a high-temperature and high-concentration condition during the desmear process and repair, for example, the chances of the board whitening.

The phosphine oxide compound (B) preferably includes a phosphine oxide compound (B9) having a melting point equal to or higher than 280° C. This enables increasing the thermal decomposition temperature of the resin composition. The upper limit value of the melting point of the phosphine oxide compound (B9) may be, but does not have to be, for example, equal to or less than 400° C.

In this case, the phosphine oxide compound (B9) may include any one of the phosphine oxide compounds (B1)-(B8). That is to say, the melting point of any one of the phosphine oxide compounds (B1)-(B8) may be equal to or longer than 280° C.

The resin composition preferably further contains a reactive flame retardant. The reactive flame retardant is a flame retardant which chemically bonds to the maleimide compound (A) and/or the epoxy compound (C). Allowing the reactive flame retardant to react with the maleimide compound (A) and/or the epoxy compound (C) in this manner enables further improving the flame resistance.

The reactive flame retardant is preferably a phosphorus-containing compound (B10) having a structure expressed by the following formula (b10):

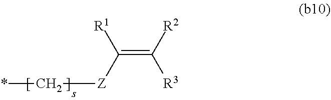

where s indicates an integer falling within the range from 1 to 10, Z indicates either an arylene group or an ester bond expressed by the following formula (b10.1), R¹ to R³ each independently indicate either a hydrogen atom or a monovalent organic group, and * indicates a bond:

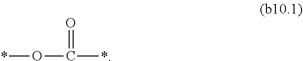

The monovalent organic group may be, but does not have to be, an alkyl group, for example. The alkyl group may be, but does not have to be, a methyl group, for example.

The structure expressed by the formula (b10) is preferably a structure expressed by either the following formula (b11.1) or the following formula (b11.2). This may further improve the chemical resistance.

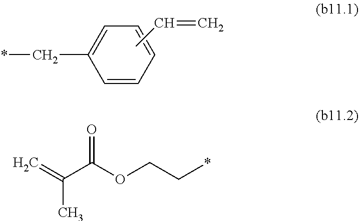

In these formulae (b11.1) and (b11.2), * indicates a bond.

The phosphorus-containing compound (B10) preferably further has a structure expressed by either the following formula (b12.1) or the following formula (b12.2). This may further improve the chemical resistance.

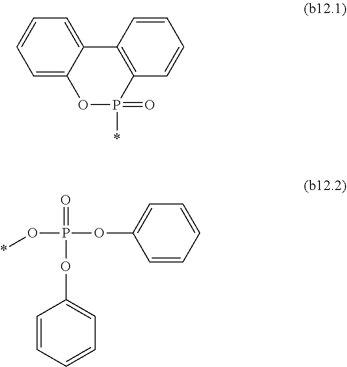 [SMILES: *P1(=O)Oc2ccccc2-c2ccccc21 ; *OP(=O)(Oc1ccccc1)Oc1ccccc1]

In these formulae (b12.1) and (b12.2), * indicates a bond.

The phosphorus-containing compound (B10) preferably has both the structure expressed by either the formula (b11.1) or the formula (b11.2) and the structure expressed by either the formula (b12.1) or the formula (b12.2). The phosphorus-containing compound (B10) preferably includes a phosphorus-containing compound (B13) expressed by the following formula (b13). The phosphorus-containing compound (B13) is diphenyl-2-methacryloyloxyethyl phosphate.

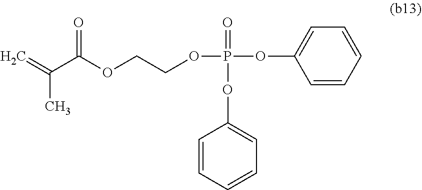 [SMILES: C=C(C)C(=O)OCCOP(=O)(Oc1ccccc1)Oc1ccccc1]

The content of the phosphine oxide compound (B) is preferably equal to or greater than 1 part by mass and equal to or less than 65 parts by mass, and more preferably equal to or greater than 5 parts by mass and equal to or less than 60 parts by mass, with respect to 100 parts by mass in total of the maleimide compound (A) and the epoxy compound (C).

<Epoxy Compound (C)>

The epoxy compound (C) herein refers to a compound having at least one epoxy group (preferably two or more epoxy groups) per molecule. Examples of the epoxy compounds (C) include, without limitation, naphthalene epoxy resins, biphenyl epoxy resins, dicyclopentadiene epoxy resins, and mesogen skeleton epoxy resins. The mesogen skeleton epoxy resin is an epoxy resin having at least one mesogen group per molecule. As used herein, the mesogen group has a rigid structure and is the smallest unit structure that may form a liquid crystal structure. Examples of the mesogen group include, without limitation, a biphenyl structure and a phenylbenzoate structure.

The epoxy compound (C) preferably includes an epoxy compound (C1) having an epoxy equivalent equal to or greater than 200 g/eq and equal to or less than 350 g/eq. This enables increasing the glass transition temperature (Tg) of the board. As described above, increasing Tg of the board may reduce the chances of causing cracks in the board and may increase the reliability of interlevel connection.

The ratio by mass of the maleimide compound (A) to the epoxy compound (C) preferably falls within the range from 50:50 to 95:5. In other words, the content of the epoxy compound (C) is preferably equal to or greater than 5 parts by mass and equal to or less than 50 parts by mass with respect to 100 parts by mass in total of the maleimide compound (A) and the epoxy compound (C). This enables lowering the coefficient of water absorption of the board.

<Styrene Copolymer (D)>

The resin composition preferably further contains a styrene copolymer (D). This enables further reducing the warpage of the board.

The styrene copolymer (D) has at least one type of structure derived from a styrene compound and/or a styrene derivative. Examples of the styrene compound and/or styrene derivative include, without limitation, styrene, α-methyl styrene, p-methyl styrene, a compound in which some of hydrogen atoms of these aromatic rings are replaced with an alkyl group, and polymers thereof. The styrene copolymer (D) may further have a structure derived from a conjugated diene-based compound.

The styrene copolymer (D) may be a non-hydrogenated product or a hydrogenated product, whichever is appropriate. The non-hydrogenated product herein refers to a non-hydrogenated substance. The hydrogenated product herein refers to a hydrogenated substance. The weight average molecular weight of the styrene copolymer (D) is preferably equal to or greater than 10,000 and equal to or less than 150,000.

The styrene copolymer (D) preferably includes at least one selected from the group consisting of: a methylstyrene (ethylene/butylene) methylstyrene copolymer; a methylstyrene (ethylene-ethylene/propylene) methylstyrene copolymer; a styrene-isoprene copolymer; a styrene-isoprene-styrene copolymer; a styrene (ethylene/butylene) styrene copolymer; a styrene (ethylene-ethylene/propylene) styrene copolymer; and hydrogenated products thereof. Adding such a styrene copolymer (D) to the resin composition enables further reducing the warpage of the board.

If the resin composition further contains the styrene copolymer (D), the content of the styrene copolymer (D) is preferably equal to or greater than 10 parts by mass and equal to or less than 40 parts by mass with respect to 100 parts by mass in total of the maleimide compound (A), the epoxy compound (C), and the styrene copolymer (D). This enables further reducing the warpage of the board.

<Inorganic Filler (E)>

The resin composition preferably further contains an inorganic filler (E). This enables further improving the flame resistance of the board and may also reduce the linear expansivity of the board.

The inorganic filler (E) preferably contains at least one selected from the group consisting of metal oxides, metal hydroxides, talc, aluminum borate, barium sulfate, calcium carbonate, and zinc molybdate. Examples of the metal oxides include, without limitation, silica, alumina, titanium oxide, and mica. Examples of the metal hydroxides include, without limitation, aluminum hydroxide and magnesium hydroxide.

The inorganic filler (E) is preferably surface-treated with a surface treatment agent. This improves the wettability of the inorganic filler (E) with the maleimide compound (A), the phosphine oxide compound (B), the epoxy compound (C), and the styrene copolymer (D) and thereby improves the dispersibility of the inorganic filler (E). Examples of the surface treatment agents include, without limitation, silane coupling agents, titanate coupling agents, aliphatic acid, and surfactants. The silane coupling agent preferably includes at least one functional group selected from the group consisting of a vinyl group, an epoxy group, a styryl group, a methacrylic group, an acrylic group, an amino group, an isocyanurate group, a ureido group, a mercapto group, an isocyanate group, and an acid anhydride group.

The inorganic filler (E) preferably has a spherical shape. This may increase the flowability of the resin composition during the molding process.

The mean particle size of the inorganic filler (E) is preferably equal to or greater than 0.01 μm and equal to or less than 50 μm and more preferably equal to or greater than 0.05 μm and equal to or less than 20 μm. Note that the mean particle size herein refers to a particle size at an integrated value of 50% in a particle size distribution obtained by laser diffraction and scattering method.

If the resin composition further contains the inorganic filler (E), the content of the inorganic filler (E) is preferably equal to or greater than 30 parts by mass and equal to or less than 200 parts by mass, and more preferably equal to or greater than 50 parts by mass and equal to or less than 150 parts by mass, with respect to 100 parts by mass in total of the maleimide compound (A), the epoxy compound (C), and the styrene copolymer (D). Note that in that case, the resin composition may contain no styrene copolymer (D).

<Other Components (F)>

The resin composition may further contain other components (F). Examples of the other components include, without limitation, catalytic curing agents, cross-linking agents, reaction initiators, resin modifiers, antifoaming agents, heat stabilizers, antistatic agents, ultraviolet absorbers, dyes, pigments, lubricants, dispersants such as a wet dispersant, and leveling agents. The catalytic curing agents include an imidazole compound such as 2-ethyl-4-methylimidazole. The content of the other components (F) is not limited to any particular value unless the advantages of this embodiment are reduced.

<Form>

The resin composition may have any form without limitation. That is to say, the resin composition may be in liquid form or in solid form, whichever is appropriate. The liquid form includes a varnish form. A varnish may be prepared by mixing the resin composition with a solvent and stirring up the mixture. Examples of the solvents include, without limitation, toluene, methyl ethyl ketone, cyclohexanone, and propylene glycol monomethyl ether acetate.

(2) Prepreg

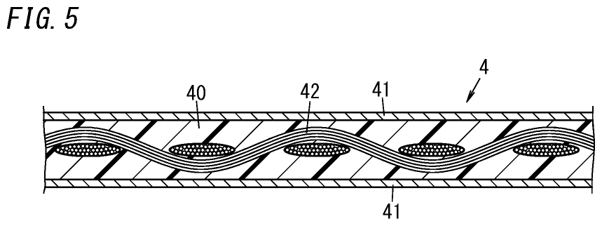

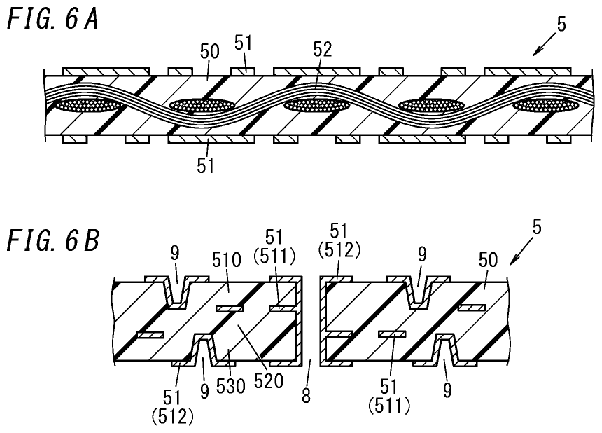

FIG. 1 illustrates a prepreg 1 according to this embodiment. The prepreg 1 has the shape of a sheet or a film as a whole. That is to say, the prepreg 1 extends in the X direction and the Y direction. The prepreg 1 may be used as a material for the metal-clad laminate 4, as a material for the printed wiring board 5, and to make a printed wiring board 5 with multiple levels (by buildup process). When heated or irradiated with light (e.g., an ultraviolet ray), the prepreg 1 is cured to turn into a cured product. The cured product is a substance in a cured state (i.e., in an insoluble and non-meltable state). The cured product of the prepreg 1 may form an insulating layer 40 of the metal-clad laminate 4 or an insulating layer 50 of the printed wiring board 5 (see FIGS. 5-6B).

The prepreg 1 includes: a base member 11; and a resin layer 10 containing either a resin composition or a semi-cured product of the resin composition, each of which is impregnated into the base member 11. A sheet of the prepreg 1 includes at least one base member 11.

A material for the base member 11 is not limited to any particular one but may be, for example, a woven fabric or a nonwoven fabric.

Examples of the woven fabric include, without limitation, glass cloth, aramid cloth, and polyester cloth.

Examples of the nonwoven fabric include, without limitation, glass nonwoven fabric, aramid nonwoven fabric, polyester nonwoven fabric, pulp paper, and linter paper.

Examples of the glass fiber as a constituent material for the glass cloth and the glass nonwoven fabric include, without limitation, Q glass, NE glass, E glass, S glass, T glass, L glass, and L2 glass.

The base member 11 preferably has a thickness equal to or greater than 5 μm and equal to or less than 300 μm and more preferably has a thickness equal to or greater than 10 μm and equal to or less than 200 μm.

The surface of the base member 11 may be subjected to surface treatment with a silane coupling agent. The silane coupling agent may be, but does not have to be, a silane coupling agent having at least one functional group selected from the group consisting of, for example, a vinyl group, an epoxy group, a styryl group, a methacrylic group, an acrylic group, an amino group, an isocyanurate group, a ureido group, a mercapto group, an isocyanate group, and an acid anhydride group.

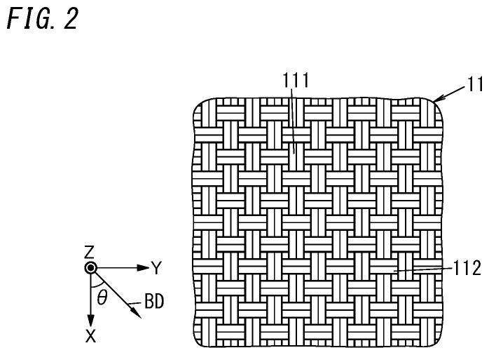

FIG. 2 illustrates an exemplary base member 11. The base member 11 is a piece of woven fabric in which a warp 111 and a woof 112 are woven. The direction (X direction) of the warp 111 and the direction (Y direction) of the woof 112 intersect with each other at right angles. The base member 11 extends in the X direction and the Y direction. A biasing direction BD is a direction intersecting with the direction (X direction) of the warp 111. The angle formed between the biasing direction BD and the direction (X direction) of the warp 111 is θ (which may be 45 degrees, for example).

The resin layer 10 may be either a resin layer containing a resin composition (in a first case) or a resin layer containing a semi-cured product of the resin composition (in a second case).

In the first case, the resin layer 10 may be formed in the following manner. Specifically, the resin layer 10 may be formed by impregnating a varnish of the resin composition into the base member 11 and then vaporizing the solvent. This resin layer 10 is formed as an unreacted resin composition (which is a dried product thereof). As used herein, the “unreacted state” includes a completely unreacted state and a hardly unreacted state. When heated, the resin layer 10 turns from the unreacted state into a cured state.

On the other hand, in the second case, the resin composition is in a semi-cured state. As used herein, the “semi-cured state” refers to an intermediate stage (Stage B) of a curing reaction. The intermediate stage is a stage between Stage A in the state of a varnish and Stage C in a fully cured state. In the second case, the resin layer 10 may be formed in the following manner. Specifically, the resin layer 10 may be formed by impregnating the base member 11 with a varnish of the resin composition, heating the base member 11 to vaporize the solvent, and advancing the curing reaction of the resin composition to the intermediate stage. This resin layer 10 is made of the resin composition in the semi-cured state (i.e., a semi-cured product of the resin composition).

As can be seen from the foregoing description, the degree of advancement of the curing reaction of the resin layer 10 varies according to the resin composition to use.

The thickness (i.e., thickness measured in the Z direction) of the prepreg 1 may be, but does not have to be, equal to or greater than 10 μm and equal to or less than 120 μm. This may achieve the advantage of reducing the thickness of the board.

As can be seen, the resin layer 10 of the prepreg 1 according to this embodiment is made of the resin composition described above, thus enabling improving the flame resistance, the chemical resistance, and the electrical characteristics.

(3) Film with Resin

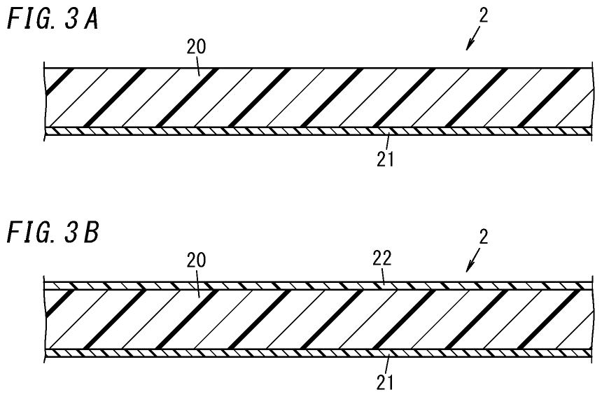

FIG. 3A illustrates a film 2 with resin according to this embodiment. The film 2 with resin has the shape of a film or sheet as a whole. The film 2 with resin includes: a resin layer 20 containing the resin composition or a semi-cured product of the resin composition; and a supporting film 21 that supports the resin layer 20. The film 2 with resin may be used, for example, to form a printed wiring board 5 with multiple levels (by buildup process).

When heated or irradiated with light (e.g., an ultraviolet ray), the resin layer 20 is cured to form the insulating layer 40 of the metal-clad laminate 4 or the insulating layer 50 of the printed wiring board 5 (see FIGS. 5-6B). The resin layer 20 is the same as the resin layer 10 of the prepreg 1 except that the resin layer 20 is not impregnated into the base member 11.

The thickness of the resin layer 20 is not limited to any particular value but may be, for example, equal to or greater than 10 μm and equal to or less than 120 μm. This enables reducing the thickness of the board.

The supporting film 21 supports the resin layer 20 thereon. Supporting the resin layer 20 in this way allows the resin layer 20 to be handled more easily. The supporting film 21 may be peeled off from the resin layer 20 as needed. After the resin layer 20 has been cured to form the insulating layer 40, the supporting film 21 is preferably peeled off from the insulating layer 40. The same statement applies to a situation where the insulating layer 50 is formed out of the resin layer 20.

The supporting film 21 may be, but does not have to be, an electrically insulating film, for example. Specific examples of the supporting film 21 include a polyethylene terephthalate (PET) film, a polyimide film, a polyester film, a polyparabanic acid film, a polyether ether ketone film, a polyphenylene sulfide film, an aramid film, a polycarbonate film, and a polyarylate film. However, these are only examples and the supporting film 21 does not have to be one of these films.

Although one surface of the resin layer 20 is covered with the supporting film 21 in the example shown in FIG. 3A, the other surface of the resin layer 20 may be covered with a protective film 22 with the one surface of the resin layer 20 covered with the supporting film 21 as shown in FIG. 3B. The protective film 22, as well as the supporting film 21, may also be peeled off from the resin layer 20 as needed. Covering both surfaces of the resin layer 20 in this manner allows the resin layer 20 to be handled even more easily. This also reduces the chances of foreign particles adhering onto the resin layer 20.

The protective film 22 may be, but does not have to be, an electrically insulating film, for example. Specific examples of the protective film 22 include a polyethylene terephthalate (PET) film, a polyolefin film, a polyester film, and a polymethylpentene film. However, these are only examples and the protective film 22 does not have to be one of these films.

As can be seen, the resin layer 20 of the film 2 with resin according to this embodiment is made of the resin composition described above, thus enabling improving the flame resistance, the chemical resistance, and the electrical characteristics.

(4) Sheet of Metal Foil with Resin

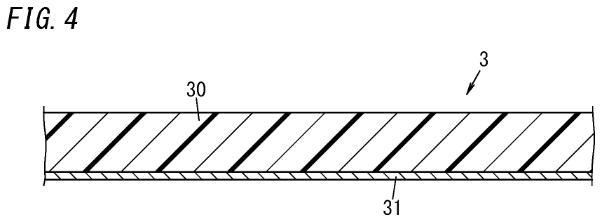

FIG. 4 illustrates a sheet of metal foil 3 with resin according to this embodiment. The sheet of metal foil 3 with resin has the shape of a film or sheet as a whole. The sheet of metal foil 3 with resin includes: a resin layer 30 containing the resin composition or a semi-cured product of the resin composition; and a sheet of metal foil 31 bonded to the resin layer 30. The sheet of metal foil 3 with resin may be used, for example, to form a printed wiring board 5 with multiple levels (by buildup process).

When heated or irradiated with light (e.g., an ultraviolet ray), the resin layer 30 is cured to form the insulating layer 40 of the metal-clad laminate 4 or the insulating layer 50 of the printed wiring board 5 (see FIGS. 5-6B). The resin layer 30 is the same as the resin layer 10 of the prepreg 1 except that the resin layer 30 is not impregnated into the base member 11.

The thickness of the resin layer 30 is not limited to any particular value but may be, for example, equal to or greater than 10 μm and equal to or less than 120 μm. This enables reducing the thickness of the board.

The sheet of metal foil 31 is bonded onto the resin layer 30. The sheet of metal foil 31 may specifically be, but does not have to be, a sheet of copper foil, a sheet of aluminum foil, or a sheet of nickel foil. The sheet of metal foil 31 may be patterned into conductor wiring 51 by having unnecessary portions thereof etched away by subtractive process, for example (see FIG. 6A, for example).

The thickness of the sheet of metal foil 31 is not limited to any particular value but is preferably equal to or greater than 0.2 μm and equal to or less than 35 μm.

If the sheet of metal foil 31 is configured as an extremely thin sheet of metal foil, then the sheet of metal foil 31 preferably forms part of an extremely thin sheet of metal foil with a carrier from the viewpoint of improving its handleability. The extremely thin sheet of metal foil with the carrier includes the sheet of metal foil 31 (extremely thin sheet of metal foil), a peelable layer, and a carrier. In that case, the sheet of metal foil 31 has a thickness equal to or less than 10 μm, for example. The peelable layer is used to temporarily bond the sheet of metal foil 31 to the carrier. The sheet of metal foil 31 is peeled off as needed from the peelable layer. The carrier is a support for supporting the sheet of metal foil 31 thereon. Specific examples of the carrier include a sheet of copper foil and a sheet of aluminum foil. The carrier is thicker than the sheet of metal foil 31.

As can be seen, the resin layer 30 of the sheet of metal foil 3 with resin according to this embodiment is made of the resin composition described above, thus enabling improving the flame resistance, the chemical resistance, and the electrical characteristics.

(5) Metal-Clad Laminate

FIG. 5 illustrates a metal-clad laminate 4 according to this embodiment. The metal-clad laminate 4 includes an insulating layer 40 and metal layers 41 bonded to the insulating layer 40. The insulating layer 40 includes either a cured product of the resin composition or a cured product of the prepreg 1. The metal-clad laminate 4 may be used, for example, as a material for the printed wiring board 5.

Although the single insulating layer 40 includes a single base member 42 in the example illustrated in FIG. 5, the single insulating layer 40 may include two or more base members 42.

The thickness of the insulating layer 40 is not limited to any particular value but may be, for example, equal to or greater than 10 μm and equal to or less than 120 μm. This enables reducing the thickness of the board.

Although the metal layers 41 are bonded to both surfaces of the insulating layer 40 in the example illustrated in FIG. 5, the metal layer 41 may be bonded to only one surface of the insulating layer 40. The metal-clad laminate 4 having the metal layers 41 bonded to both surfaces of the insulating layer 40 is a double-sided metal-clad laminate. The metal-clad laminate 4 having the metal layer 41 bonded to only surface of the insulating layer 40 is a single-sided metal-clad laminate.

The metal layer 41 may be, but does not have to be, a sheet of metal foil, for example. The sheet of metal foil may be, but does not have to be, a sheet of copper foil, a sheet of aluminum foil, or a sheet of nickel foil, for example.

The thickness of the metal layer 41 is not limited to any particular value but may be, for example, equal to or greater than 0.2 μm and equal to or less than 35 μm. If the metal layer 41 is configured as an extremely thin sheet of metal foil, then the metal layer 41 preferably forms part of an extremely thin sheet of metal foil with a carrier from the viewpoint of improving its handleability. The extremely thin sheet of metal foil with a carrier is as described above.

As can be seen, the insulating layer 40 of the metal-clad laminate 4 according to this embodiment is made of the resin composition described above, thus enabling improving the flame resistance, the chemical resistance, and the electrical characteristics.

(6) Printed Wiring Board

FIGS. 6A and 6B illustrate printed wiring boards 5 according to this embodiment. Each of the printed wiring boards 5 includes an insulating layer 50 and conductor wiring 51 formed on the insulating layer 50. The insulating layer 50 includes either a cured product of the resin composition or a cured product of the prepreg 1.

The printed wiring board 5 shown in FIG. 6A includes a single insulating layer 50. In FIG. 6A, the single insulating layer 50 includes a single base member 52. However, this is only an example and should not be construed as limiting. Alternatively, the single insulating layer 50 may include two or more base members 52. On the other hand, the printed wiring board 5 shown in FIG. 6B includes a plurality of (specifically, three) insulating layers 50, namely, a first insulating layer 510, a second insulating layer 520, and a third insulating layer 530. These three insulating layers 50 are stacked in this order one on top of another in the thickness direction and are bonded to each other. In FIG. 6B, each of the first insulating layer 510, the second insulating layer 520, and the third insulating layer 530 may include no base member 52 or include one or more base members 52. As can be seen, the insulating layer 50 is the same as the insulating layer 40 of the metal-clad laminate 4 described above.

In the printed wiring board 5 shown in FIG. 6A, the conductor wiring 51 is formed on each of the two surfaces of the insulating layer 50. Alternatively, the conductor wiring 51 may be formed on only one surface of the insulating layer 50.

On the other hand, in the printed wiring board 5 shown in FIG. 6B, the conductor wiring 51 includes an internal circuit 511 and an external circuit 512. The internal circuit 511 is located between two insulating layers 50. Specifically, the internal circuit 511 is located between the first insulating layer 510 and the second insulating layer 520 and between the second insulating layer 520 and the third insulating layer 530. The external circuit 512 is located outside of the insulating layer 50. That is to say, the external circuit 512 is formed on the surface of the first insulating layer 510 and on the surface of the third insulating layer 530. The printed wiring board 5 shown in FIG. 6B further includes a via hole 8 and blind via holes 9. The via hole 8 and the blind via holes 8 electrically connect the internal circuit 511 and the external circuit 512 to each other. That is to say, the internal circuit 511 and the external circuit 512 are interconnected via the via hole 8 and the blind via holes 9.

The conductor wiring 51 may be, but does not have to be, formed by, for example, subtractive process or semi-additive process (SAP).

As can be seen, the insulating layer 50 of the printed wiring board 5 according to this embodiment is made of the resin composition described above, thus enabling improving the flame resistance, the chemical resistance, and the electrical characteristics.

(7) Semiconductor Package

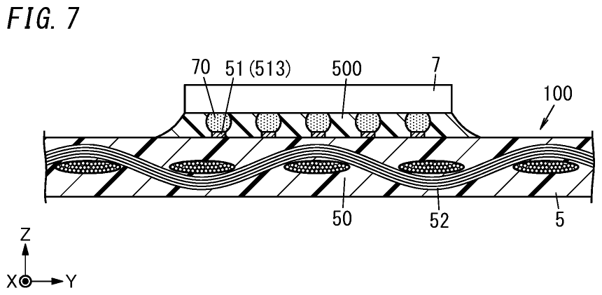

FIG. 7 illustrates a semiconductor package 100 according to this embodiment. The semiconductor package 100 includes the printed wiring board 5 and a semiconductor chip 7 mounted on the printed wiring board 5. In this case, the printed wiring board 5 is also called a “package board,” a “module board,” or an “interposer.” The printed wiring board 5 includes at least one insulating layer 50. The insulating layer 50 includes at least one base member 52. Optionally, the insulating layer 50 may include no base member 52.

The insulating layer 50 includes the conductor wiring 51. The conductor wiring 51 includes pads 513. The pads 513 are formed on the surface of the insulating layer 50.

The semiconductor chip 7 is not limited to any particular one. The semiconductor chip 7 includes bumps 70. The bumps 70 are coupled to the pads 513. This allows the semiconductor chip 7 and the printed wiring board 5 to be electrically connected to each other.

An underfilling resin layer 500 is formed between the semiconductor chip 7 and the printed wiring board 5. The underfilling resin layer 500 is formed by filling the gap between the semiconductor chip 7 and the printed wiring board 5 with an underfilling liquid encapsulant and curing the encapsulant.

As can be seen, the semiconductor package 100 according to this embodiment includes the printed wiring board 5 described above, thus enabling improving the flame resistance, the chemical resistance, and the electrical characteristics.

### EXAMPLES

Next, the present disclosure will be described specifically by way of specific examples. Note that the examples to be described below are only examples of the present disclosure and should not be construed as limiting.

(1) Resin Composition

Materials for the resin composition are as follows:

<Maleimide Compound (A)>

«(A1) (A3)»
A maleimide compound (A3) expressed by the formula (a3), product name “BMI-689” manufactured by Designer Molecules Inc. (DMI), having a maleimide group equivalent of 345 g/ep;

«(A1) (A4)»
A maleimide compound (A4) expressed by the formula (a4), product name “BMI-1500” manufactured by Designer Molecules Inc. (DMI), having a maleimide group equivalent of 750 g/ep;

«(A1) (A5)»
A maleimide compound (A5) expressed by the formula (a5), product name “BMI-3000” manufactured by Designer Molecules Inc. (DMI), having a maleimide group equivalent of 1500 g/ep;

«(A2)»
A maleimide compound (A6) expressed by the formula (a6), product name “BMI-5100” manufactured by Daiwa Kasei Industry Co., Ltd., having a maleimide group equivalent of 221 g/ep;

<Phosphine oxide compound (B)>

<<(B1) (B9)>>
Additive flame retardant, product name “PQ-60” manufactured by Chin Yee Chemical Industries, having a melting point of 330° C.;

<<(B2) (B9)>>
Additive flame retardant, product name “BPO-13” manufactured by Katayama Chemical Industries Co., Ltd., having a melting point of 300° C.;

<<(B10)>>
Reactive flame retardant, product name “SD-5” manufactured by Sanko Co., Ltd., having a phosphorus content of 11.8% by mass and a melting point of 130° C.;

<<Phosphoric Acid Ester>>
Additive flame retardant, non-halogen condensed phosphoric acid ester (aromatic condensed phosphoric acid ester), product name “PX-200” manufactured by Daihachi Chemical Industry Co., Ltd.

<Phosphazene>
Additive flame retardant, product name “SPB-100L” manufactured by Otsuka Chemical Co., Ltd.,

<Epoxy Compound (C)>
Naphthalene epoxy resin, product name “HP-9500” manufactured by DIC Corporation, having an epoxy equivalent of 230 g/eq;
Biphenyl epoxy resin, product name “NC-3000-H” manufactured by Nippon Kayaku Co., Ltd., having an epoxy equivalent of 280-300 g/eq;

<Styrene Copolymer (D)>
Hydrogenated methylstyrene (ethylene/butylene) methylstyrene copolymer, hydrogenated styrene-based thermoplastic elastomer (SEBS), product name “Septon® V9827” manufactured by Kuraray Co., Ltd., having a weight average molecular weight of 92,000;

<Inorganic Filler (E)>
Fused silica, product name “SC2050-MTX” manufactured by Admatechs, having a mean particle size of 0.5 μm;

<Other Components (F)>
2-ethyl-4-methylimidazole, “2E4MZ” manufactured by Shikoku Chemicals Corporation; and

<PPE Resin>
Modified polyphenylene ether, product name “OPE-2St-1200” manufactured by Mitsubishi Gas Chemical Company, Inc.

The maleimide compound (A), the phosphine oxide compound (B), phosphazene, the epoxy compound (C), the styrene copolymer (D), the inorganic filler (E), and the other components (F) were compounded together to have any of the compositions shown in the following Tables 1 and 2 and mixed with a combined solvent of methyl ethyl ketone and toluene. Then, the mixture was stirred up to be homogenized. In this manner, a varnish of the resin composition was prepared.

(2) Prepreg

A prepreg was produced by impregnating the varnish into a piece of glass cloth (#2116 type, WEA116E manufactured by Nitto Boseki Co., Ltd., E glass, having a thickness of 0.1 mm) and then heating and drying the glass cloth impregnated with the varnish for about two to eight minutes. Note that in some comparative examples, the resin could not be cured.

(3) Metal-Clad Laminate

Two sheets of such prepregs were stacked one on top of the other. The stack thus obtained was sandwiched between two sheets of copper foil, each having a thickness of 12 μm. Then, the assembly was heated to 220° C. under a pressure of 3 MPa for two hours. In this manner, a double-sided copper-clad laminate (as an exemplary double-sided metal-clad laminate) having a thickness of approximately 0.2 mm was manufactured. The following tests were conducted by using this as a board for evaluation.

(4) Tests

(4.1) Flame Resistance

Test pieces, each having a length of 125 mm and a width of 12.5 mm, were cut out of the board for evaluation. The test pieces were subjected to flammability tests (vertical flame tests) ten times in accordance with “Test for Flammability of Plastic Materials—UL 94” by Underwriters Laboratories. Specifically, each of five test pieces was subjected to the flammability test twice apiece. The total time for which the test piece continued to burn during the flammability tests was obtained. The test piece was graded based on the total time as follows in terms of its flame resistance. Note that “burned” in Tables 1 and 2 means that the test piece continued to burn to the end:

(4.2) Chemical Resistance (Alkali Resistance)

First, a 15% by mass sodium aqueous solution was heated to 80° C. On the other hand, the sheets of copper foil on both surfaces of the board for evaluation were etched away to obtain an unclad plate. Next, the unclad plate was immersed for 15 minutes in the sodium aqueous solution that had been heated to 80° C. Thereafter, the unclad plate was picked out of the sodium aqueous solution. The unclad plate was observed with the naked eye and thereby graded as follows in terms of its chemical resistance:
Grade A: if the unclad plate did not whiten; or
Grade B: if the unclad plate whitened.

Note that if the unclad plate was originally white and it was difficult to determine, with the naked eye, whether or not the unclad plate whitened, the unclad plate was graded as follows in terms of its chemical resistance:
Grade A: if the mass loss rate of the unclad plate before and after the immersion was less than 0.5% by mass; or
Grade B: if the mass loss rate of the unclad plate before and after the immersion was equal to or greater than 0.5% by mass.

Note that the “mass loss rate” of the unclad plate before and after the immersion is the ratio of the difference in the mass of the unclad plate before and after the immersion to the mass of the unclad plate before the immersion (=(mass before immersion−mass after immersion)/mass before immersion×100).

(4.3) Heat Resistance

A test piece having dimensions of 5 cm×5 cm was cut out of the board for evaluation and then loaded into a dryer at 290° C. for 1 hour. Thereafter, the test piece was unloaded from the dryer, observed with the naked eye, and graded as follows in terms of its heat resistance:
Grade A: if the test piece did not swell; or
Grade B: if the test piece swelled.

(4.4) Dielectric Loss Tangent

The dielectric loss tangent of the board for evaluation at 1 GHz was measured by the method in compliance with IPC-TM650-2.5.5.9. Specifically, using an impedance analyzer (RF impedance analyzer HP4291B manufactured by Agilent Technologies Japan, Ltd.), the dielectric loss tangent of the board for evaluation at 1 GHz was measured.

(4.5) Glass Transition Temperature (Tg)

First, an unclad plate was obtained by etching away the sheet of copper foil from both surfaces of the board for evaluation. Next, the glass transition temperature (Tg) of the unclad plate was measured using a viscoelasticity spectrometer (DMS100) manufactured by Seiko Instruments, Inc. At this time, a dynamic mechanical analysis (DMA) was carried out using a bending module with the frequency set at 10 Hz. The temperature at which the loss tangent (tan δ) reached a local maximum when the temperature was increased from room temperature to 320° C. at a temperature increase rate of 5° C./min was defined to be the glass transition temperature (Tg).

TABLE 1

| | | | | | Examples | | | | | | | | | |
|---|---|---|---|---|---|---|---|---|---|---|---|---|---|---|
| | | | | | 1 | 2 | 3 | 4 | 5 | 6 | 7 | 8 | 9 | 10 |
| Compo- | Maleimide | (A1) | BMI-689 | Parts | 0 | 0 | 50 | 0 | 0 | 50 | 0 | 0 | 0 | 0 |
| sition | com- | (A3) | | by | | | | | | | | | | |
| | pound | | | mass | | | | | | | | | | |
| | (A) | (A1) | BMI- | Parts | 0 | 0 | 0 | 50 | 0 | 0 | 0 | 0 | 0 | 0 |
| | | (A4) | 1500 | by | | | | | | | | | | |
| | | | | mass | | | | | | | | | | |
| | | (A1) | BMI- | Parts | 50 | 50 | 0 | 0 | 50 | 0 | 50 | 50 | 50 | 20 |
| | | (A5) | 3000 | by | | | | | | | | | | |
| | | | | mass | | | | | | | | | | |
| | | (A2) | BMI- | Parts | 0 | 0 | 0 | 0 | 20 | 0 | 0 | 20 | 35 | 30 |
| | | | 5100 | by | | | | | | | | | | |
| | | | | mass | | | | | | | | | | |
| | Phos- | (B1) | PQ-60 | Parts | 30 | 0 | 30 | 30 | 30 | 30 | 30 | 30 | 30 | 30 |
| | phine | (B9) | | by | | | | | | | | | | |
| | oxide | additive | | mass | | | | | | | | | | |
| | com- | (B2) | BPO-13 | Parts | 0 | 30 | 0 | 0 | 0 | 0 | 0 | 0 | 0 | 0 |
| | pound | (B9) | | by | | | | | | | | | | |
| | (B) | additive | | mass | | | | | | | | | | |
| | | (B10) | SD-5 | Parts | 0 | 0 | 0 | 0 | 0 | 0 | 10 | 10 | 10 | 10 |
| | | reactive | | by | | | | | | | | | | |
| | | | | mass | | | | | | | | | | |
| | | Additive | PX-200 | Parts | 0 | 0 | 0 | 0 | 0 | 0 | 0 | 0 | 0 | 0 |
| | | (phos- | | by | | | | | | | | | | |
| | | phoric | | mass | | | | | | | | | | |
| | | acid | | | | | | | | | | | | |
| | | ester) | | | | | | | | | | | | |
| | Phos- | Additive | SPB- | Parts | 0 | 0 | 0 | 0 | 0 | 0 | 0 | 0 | 0 | 0 |
| | phazene | | 100 L | by | | | | | | | | | | |
| | | | | mass | | | | | | | | | | |

| | | | | | | | | | | | | | |
|---|---|---|---|---|---|---|---|---|---|---|---|---|---|
| | Epoxy | HP-9500 | Parts | 0 | 0 | 0 | 0 | 30 | 50 | 0 | 0 | 0 | 0 |
| | compound (C) | | by | | | | | | | | | | |
| | | | mass | | | | | | | | | | |
| | | NC- | Parts | 50 | 50 | 50 | 50 | 0 | 0 | 40 | 20 | 5 | 20 |
| | | 3000-H | by | | | | | | | | | | |
| | | | mass | | | | | | | | | | |
| | Styrene | V9827 | Parts | 0 | 0 | 0 | 0 | 0 | 0 | 0 | 0 | 0 | 20 |
| | copolymer (D) | | by | | | | | | | | | | |
| | | | mass | | | | | | | | | | |
| | Inorganic filler (E) | SC2050- | Parts | 100 | 100 | 100 | 100 | 100 | 100 | 100 | 100 | 100 | 100 |
| | | MTX | by | | | | | | | | | | |
| | | | mass | | | | | | | | | | |
| | Other | 2E4MZ | Parts | 1 | 1 | 1 | 1 | 1 | 1 | 1 | 1 | 1 | 1 |
| | components (F) | | by | | | | | | | | | | |
| | | | mass | | | | | | | | | | |
| | PPE resin | OPE-2St- | Parts | 0 | 0 | 0 | 0 | 0 | 0 | 0 | 0 | 0 | 0 |
| | | 1200 | by | | | | | | | | | | |
| | | | mass | | | | | | | | | | |
| Evalu- | Flame resistance | UL94 | s | 130 | 135 | 125 | 128 | 130 | 130 | 80 | 80 | 85 | 80 |
| ation | | vertical | | | | | | | | | | | |
| | | flame | | | | | | | | | | | |
| | | test | | | | | | | | | | | |
| | Chemical resistance | Alkali | — | A | A | A | A | A | A | A | A | A | A |
| | | resistance | | | | | | | | | | | |
| | Heat resistance | 290° C. | — | A | A | A | A | A | A | A | A | A | A |
| | | 1 h | | | | | | | | | | | |
| | Dielectric | Df | — | 0.008 | 0.008 | 0.008 | 0.008 | 0.006 | 0.008 | 0.007 | 0.006 | 0.005 | 0.005 |
| | loss tangent | | | | | | | | | | | | |
| | Glass transition | DMA | ° C. | 260 | 255 | 260 | 260 | 270 | 250 | 235 | 250 | 270 | 260 |
| | temperature (Tg) | | | | | | | | | | | | |

TABLE 2

| | | | | | Comparative examples | | | | | |
|---|---|---|---|---|---|---|---|---|---|---|
| | | | | | 1 | 2 | 3 | 4 | 5 | 6 |
| Composition | Maleimide | (A1) (A3) | BMI-689 | Parts by mass | 0 | 0 | 0 | 0 | 0 | 0 |
| | compound | (A1) (A4) | BMI-1500 | Parts by mass | 0 | 0 | 0 | 0 | 0 | 0 |
| | (A) | (A1) (A5) | BMI-3000 | Parts by mass | 50 | 50 | 50 | 0 | 100 | 0 |
| | | (A2) | BMI-5100 | Parts by mass | 0 | 0 | 0 | 0 | 0 | 0 |
| | Phosphine | (B1) (B9) additive | PQ-60 | Parts by mass | 0 | 0 | 0 | 30 | 30 | 30 |
| | oxide | (B2) (B9) additive | BPO-13 | Parts by mass | 0 | 0 | 0 | 0 | 0 | 0 |
| | compound | (B10) reactive | SD-5 | Parts by mass | 0 | 0 | 0 | 0 | 0 | 0 |
| | (B) | Additive (phosphoric | PX-200 | Parts by mass | 0 | 0 | 30 | 0 | 0 | 0 |
| | | acid ester) | | | | | | | | |
| | Phosphazene | Additive | SPB-100 L | Parts by mass | 0 | 30 | 0 | 0 | 0 | 0 |

| | | | | | | | | | |
|---|---|---|---|---|---|---|---|---|---|
| | Epoxy compound (C) | HP-9500 | Parts by mass | 5 | 50 | 50 | 100 | 0 | 50 |
| | | NC-3000-H | Parts by mass | 0 | 0 | 0 | 0 | 0 | 0 |
| | Styrene copolymer (D) | V9827 | Parts by mass | 0 | 0 | 0 | 0 | 0 | 0 |
| | Inorganic filler (E) | SC2050-MTX | Parts by mass | 100 | 100 | 100 | 100 | 100 | 100 |
| | Other components (F) | 2E4MZ | Parts by mass | 1 | 1 | 1 | 1 | 1 | 1 |
| | PPE resin | OPE-2St-1200 | Parts by mass | 0 | 0 | 0 | 0 | 0 | 50 |
| Evaluation | Flame resistance | UL94 vertical | s | burned | 130 | Resin | 80 | burned | 110 |
| | | flame test | | | | was not | | | |
| | Chemical resistance | Alkali resistance | — | A | B | cured | A | A | A |
| | Heat resistance | 290° C. 1 h | — | A | B | | A | A | A |
| | Dielectric loss tangent | Df | — | 0.009 | 0.009 | | 0.020 | 0.002 | 0.010 |
| | Glass transition | DMA | ° C. | 260 | 260 | | 270 | 80 | 245 |
| | temperature (Tg) | | | | | | | | |

### REFERENCE SIGNS LIST

1 Prepreg
10 Resin Layer
11 Base Member
2 Film with Resin
20 Resin Layer
21 Supporting Film
3 Sheet of Metal Foil with Resin
30 Resin Layer
31 Sheet of Metal Foil
4 Metal-Clad Laminate
40 Insulating Layer
41 Metal Layer
5 Printed Wiring Board
50 Insulating Layer
51 Conductor Wiring

1. A resin composition containing a maleimide compound (A), a phosphine oxide compound (B), and an epoxy compound (C),
the maleimide compound (A) including a maleimide compound (A1) having an alkyl group, of which a carbon number is equal to or greater than six, and/or an alkylene group, of which a carbon number is equal to or greater than six,
the phosphine oxide compound (B) having a structure expressed by the following formula (b0): 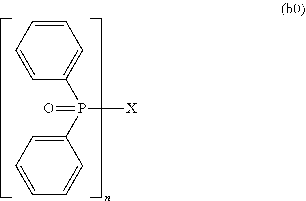
where X is a monovalent or divalent hydrocarbon group having at least one aromatic ring or an alkylene group and n is either 1 or 2.

2. The resin composition of claim 1, wherein
the phosphine oxide compound (B) includes a phosphine oxide compound (B9) having a melting point equal to or higher than 280° C.

3. The resin composition of claim 1, further containing a reactive flame retardant.

4. The resin composition of claim 1, wherein
the maleimide compound (A1) has a maleimide group equivalent equal to or greater than 400 g/eq.

5. The resin composition of claim 1, wherein
the maleimide compound (A) further includes a maleimide compound (A2) having a maleimide group equivalent less than 400 g/eq.

6. The resin composition of claim 1, wherein
the maleimide compound (A) includes at least one selected from the group consisting of: a maleimide compound (A3) expressed by the following formula (a3); a maleimide compound (A4) expressed by the following formula (a4); and a maleimide compound (A5) expressed by the following formula (a5): 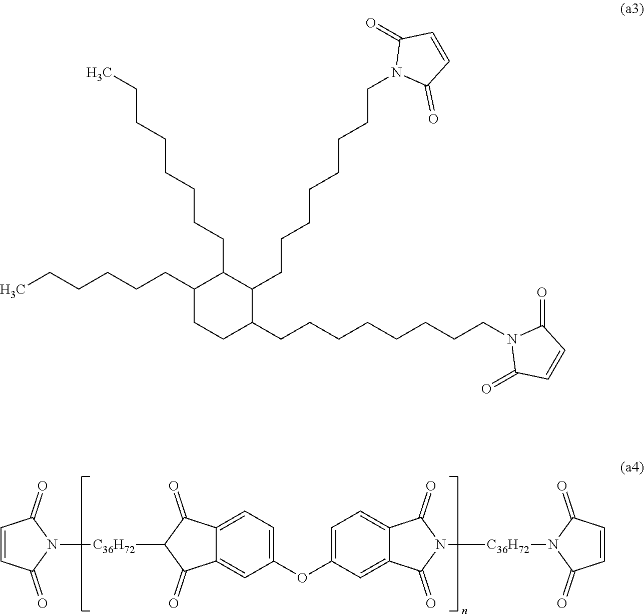
where n is an integer falling within a range from 1 to 10, 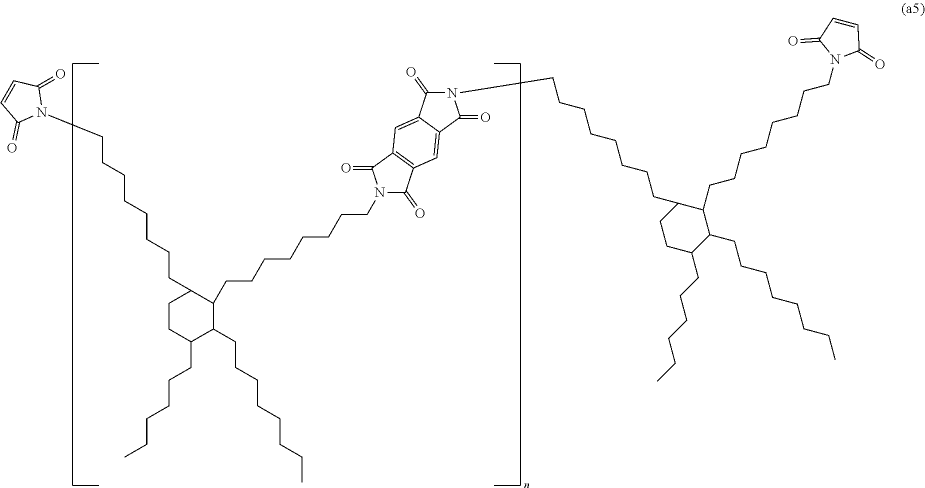
where n is an integer falling within a range from 1 to 10.

7. The resin composition of claim 1, wherein
a ratio by mass of the maleimide compound (A) to the epoxy compound (C) falls within the range from 50:50 to 95:5.

8. The resin composition of claim 1, wherein
the epoxy compound (C) includes an epoxy compound (C1) having an epoxy equivalent equal to or greater than 200 g/eq and equal to or less than 300 g/eq.

9. The resin composition of claim 1, further containing a styrene copolymer (D).

10. A prepreg comprising: a base member; and a resin layer containing either the resin composition of claim 1 or a semi-cured product of the resin composition, the resin composition or the semi-cured product of the resin composition being impregnated into the base member.

11. A film with resin, comprising: a resin layer containing either the resin composition of claim 1 or a semi-cured product of the resin composition; and a supporting film supporting the resin layer.

12. A sheet of metal foil with resin, comprising: a resin layer containing either the resin composition of claim 1 or a semi-cured product of the resin composition; and a sheet of metal foil bonded to the resin layer.

13. A metal-clad laminate comprising: an insulating layer containing either a cured product of the resin composition of claim 1; and a metal layer bonded to the insulating layer.

14. A printed wiring board comprising: an insulating layer containing either a cured product of the resin composition of claim 1; and conductor wiring formed on the insulating layer.
